(19) United States
(12) Patent Application Publication
(10) Pub. No.: US 2013/0328097 A1
(43) Pub. Date: Dec. 12, 2013

(54) GROUP III NITRIDE SEMICONDUCTOR LIGHT-EMITTING ELEMENT

(71) Applicant: Toyoda Gosei Co., LTD., Kiyosu-shi (JP)

(72) Inventors: Naoyuki NAKADA, Kiyosu-shi (JP); Yasuhisa Ushida, Kiyosu-shi (JP)

(21) Appl. No.: 13/914,433

(22) Filed: Jun. 10, 2013

(30) Foreign Application Priority Data
Jun. 11, 2012 (JP) 2012-131702

(51) Int. Cl. H01L 33/38

(52) U.S. Cl. CPC H01L 33/38
USPC 257/99

(57) ABSTRACT

A group III nitride semiconductor light-emitting element having a rectangular shape in a planar view, the element comprises an n-electrode connecting to an n-type layer and a p-electrode connecting to a p-type layer, on a same plane side; wherein the n-electrode has a n-wiring-shaped part that is wiring-shaped and extending along a first side of the rectangular shape; the p-electrode has a p-wiring-shaped part that is wiring-shaped and extending along the first side of the rectangular shape; when a distance that is between the n-wiring-shaped part and the p-wiring-shaped part is a, and a distance that is between the one side of the rectangular shape and at least one of the n-wiring-shaped part and the p-wiring-shaped part and that is nearest to the first side is b, the n-wiring-shaped part and the p-wiring-shaped part are arranged such that the distances a and b satisfy 1.65≦a/b≦7.00.

### BACKGROUND OF THE INVENTION

1. Field of the Invention

The present invention relates to a rectangular group III nitride semiconductor light-emitting element having an n-electrode and a p-electrode on the same plane side. In particular, the invention relates to a group III nitride semiconductor light-emitting element in which the n-electrode and the p-electrode have an n-wiring-shaped part and a p-wiring-shaped part, that are extended in a long side direction, respectively.

2. Description of the Related Art

In recent years, a group III nitride semiconductor light-emitting element is becoming to be widely used in general lighting, a backlight of liquid crystal, and the like. A face-up type or flip-chip type element in which an n-electrode and a p-electrode are provided on the same plane side, and light is extracted from the face at the n-electrode and p-electrode formed side is generally used as the group III nitride semiconductor light-emitting element.

A side-view type LED package is known as a light-emitting device using a group III nitride semiconductor light-emitting element for a backlight of liquid crystal. The side-view type LED package is an elongated rectangular package, and has a structure that light is emitted from a side. Because the package has an elongated shape, when an element of a long rectangle is used as the group III nitride semiconductor element to be amounted, light output can be efficiently enhanced. Furthermore, with reduction in thickness of a liquid crystal display, an element having a shape narrower than that of a side-view type LED package is desired. For this reason, formation of a long element is progressing in the group III nitride semiconductor light-emitting element used in such an element.

Where the group III nitride semiconductor element has a long shape, diffuseness of electric current is deteriorated, electric current concentrates in a partial region, thereby uniform light emission is not achieved, and as a result, light emission efficiency is deteriorated. For this reason, a technology of enhancing diffuseness of electric current is required.

As the technology, there is a method of forming a structure that an n-electrode and a p-electrode have an n-wiring-shaped part and p-wiring-shaped part, that are extended in a wiring shape, and efficiently diffusing electric current by the n-wiring-shaped part and the p-wiring-shaped part (for example, JP-A-2004-56109, JP-A-2002-319704, JP-A-2001-345480, JP-A-2005-39284, JP-A-2006-310893). JP-A-2004-56109 indicates that an n-wiring-shaped part and a p-wiring-shaped part are arranged alternately in parallel to each other at equal intervals. JP-A-2002-319704 indicates an n-wiring-shaped part and a p-wiring-shaped part, having various patterns such as a stripe shape, a spiral shape and a concentric shape. JP-A-2001-345480 indicates a rectangular group III nitride semiconductor light-emitting element in which an n-wiring-shaped part and a p-wiring-shaped part are formed into a pattern such as a comb shape. JP-A-2005-39284 indicates a constitution that an n-wiring-shaped part and a p-wiring-shaped part, linearly extending in a direction along a side of an outer periphery of an element or in a diagonal direction of an element, are arranged alternately. JP-A-2006-310893 indicates an n-wiring-shaped part and a p-wiring-shaped part, linearly extending to a longitudinal direction of an element, in a rectangular light-emitting element.

However, even though the wiring-shaped parts are arranged according to the methods described in the above patent documents in a long group III nitride semiconductor light-emitting element, electric current concentrates locally, emission of light cannot be sufficiently uniformed, and deterioration of light emission efficiency is unavoidable. Furthermore, any of the above patent documents do not consider the distance of from a wiring-shaped part to an outer periphery of an element

### SUMMARY OF THE INVENTION

Accordingly, an object of the present invention is to suppress deterioration of light emission efficiency by preventing local concentration of electric current in a rectangular group III nitride semiconductor light-emitting element having an n-electrode and a p-electrode on the same plane side, the n-electrode and the p-electrode each having a wiring-shaped part.

A first invention is a group III nitride semiconductor light-emitting element having a rectangular shape in a planar view, the element comprises an n-electrode connecting to an n-type layer and a p-electrode connecting to a p-type layer, on a same plane side; wherein the n-electrode has a n-wiring-shaped part that is wiring-shaped and extending along a first side of the rectangular shape; the p-electrode has a p-wiring-shaped part that is wiring-shaped and extending along the first side of the rectangular shape; when a distance that is between the n-wiring-shaped part and the p-wiring-shaped part is a, and a distance that is between the one side of the rectangular shape and at least one of the n-wiring-shaped part and the p-wiring-shaped part and that is nearest to the first side is b, the n-wiring-shaped part and the p-wiring-shaped part are arranged such that the distances a and b satisfy 1.65≦a/b≦7.00.

The patterns in a planar view of the n-wiring-shaped part and the p-wiring-shaped part are optional so long as the patterns are a wiring shape extending along the first side direction of the rectangular shape that is an external form in a planar view of the group III nitride semiconductor light-emitting element. The term “wiring shape” used herein is not limited to a straight line shape, but includes a curved shape in a range satisfying 1.65≦a/b≦7.00, and a curved line shape such as a zigzag shape or a wavy line shape. In the case of a straight line shape, the line is not required to extend strictly in parallel to a long side, and the line may extend in a direction of an angle in a range of from −20 to 20° to the long side.

The n-wiring-shaped part and the p-wiring-shaped part may have a part extending in a direction different from a long side direction, for example, a part extending in a short side direction, on a part thereof. However, the part is desirably 50% or less of the entire wiring-shaped part. The reason for this is that electric current is efficiently diffused.

The n-wiring-shaped part and the p-wiring-shaped part are not required to be a single line shape, and may be plural lines. Furthermore, the patterns of the n-wiring-shaped part and p-wiring-shaped part are preferably a pattern having symmetric property such as line symmetry or rotation symmetry. The reason for this is that uniformity of light emission is enhanced.

The distance a is the shortest distance between the n-wiring-shaped part 16b and the p-wiring-shaped part 17b, and the distance b is the shortest distance of from a long side of an outer periphery of the element to a wiring-shaped part extending in a long side direction of either of the n-wiring-shaped part or the p-wiring-shaped part.

The distance b is desirably a distance of 0.1 times or more the length of a short side of an outer periphery of the element. The reason for this is that uniformity of light emission can further be enhanced.

The present invention can be applied to a group III nitride semiconductor light-emitting element having a structure that an n-electrode and a p-electrode are provided on a protective film comprising an insulator, an n-wiring-shaped part is connected to an n-type layer through a via hole, and a p-wiring-shaped part is connected to a p-type layer through a via hole.

The term “rectangular shape” of the group III nitride semiconductor light-emitting element used herein is not limited to the rectangular shape including a long side. The rectangular shape may include a square shape. In addition, in a case that “rectangular shape” means the rectangular shape including the long side (not the square), the first side means the long side of the rectangular shape.

A second invention is characterized in that in the first invention, the n-wiring-shaped part and the p-wiring-shaped part are arranged such that the distance a and distance b further satisfy a/b≦3.85.

A third invention is characterized in that in the first invention, a protective film comprising an insulator is present between the n-type layer and the n-electrode, and between the p-type layer and the p-electrode, the n-wiring-shaped part of the n-electrode is connected to the n-type layer through a via hole provided in the protective film, and the p-wiring-shaped part of the p-electrode is connected to the p-type layer through the via hole.

A fourth invention is characterized in that in the first invention, the n-wiring-shaped part and the p-wiring-shaped part have a straight line shape in parallel to a long side of the rectangle.

A fifth invention is characterized in that in the first invention, in that in the first side is a long side of the rectangular shape

A sixth invention is characterized in that in the fifth invention, the element is a rectangle having a ratio of the long side to a short side of 2 or more.

When the wiring-shaped part of the n-electrode and the wiring-shaped part of the p-electrode are arranged as in the present invention, even though the element is a long rectangular group III nitride semiconductor light-emitting element, local concentration of electric current is relaxed, and as a result, light emission can be made uniform and decrease in light emission efficiency can be suppressed.

According to the second invention, not only decrease in light emission efficiency can be suppressed, but pressure resistance performance can be enhanced.

### BRIEF DESCRIPTION OF THE DRAWINGS

FIG. 1 is a plane view showing the constitution of the light-emitting element of Example 1.

FIG. 2 is a cross-sectional view showing the constitution of the light-emitting element of Example 1.

FIG. 3 is a graph showing the relationship between light output and a/b.

FIG. 4 is a graph showing the relationship between pressure resistance and a/b.

FIG. 5 is a graph showing the relationship between light output and a/b.

FIG. 6 is a view showing a pattern of other n-electrode 26 and p-electrode 27.

### DESCRIPTION OF THE PREFERRED EMBODIMENTS

Specific examples of the present invention are described below by reference to the drawings, but the present invention is not limited to the examples.

### Example 1

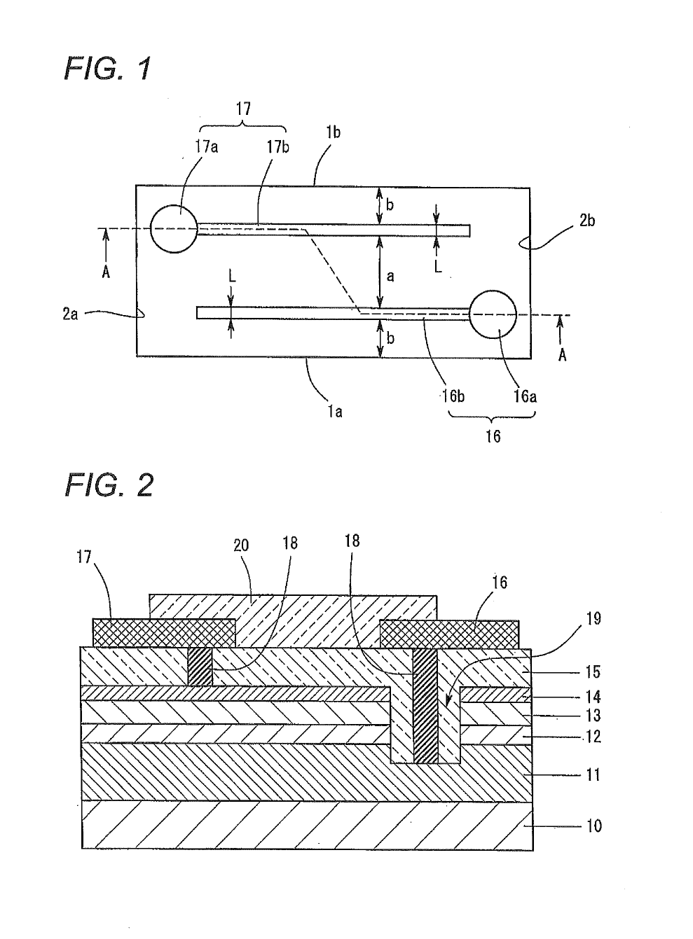

FIG. 1 is a plane view viewed from the upper part of the light-emitting element of Example 1. The light-emitting element of Example 1 has a rectangular shape in a planar view, and is a face-up type element in which a p-type layer 13 side is a light extraction face side, and an n-electrode 16 and a p-electrode 17 are provided at the light extraction face side. FIG. 2 is a cross-sectional view taken along A-A in FIG. 1.

The light-emitting element of Example 1 has a substrate 10, an n-type layer 11 comprising a group III nitride semiconductor laminated on the substrate 10 through a buffer layer (not shown) comprising AlN, a light-emitting layer 12, and a p-type layer 13, as shown in FIG. 2. A groove 19 reaching the n-type layer 11 from a partial region of a p-type layer 13 surface side is formed, and the n-type layer 11 is exposed on the bottom of the groove 19. A transparent electrode 14 is formed on the p-type layer 13. A protective film 15 that is an insulator comprising SiO₂ is formed over from the upper part of the transparent electrode 14 to the bottom of the groove 19.

An n-electrode 16 and a p-electrode are formed on the protective film 15. As shown in FIG. 1, the n-electrode has an n-pad part 16a and an n-wiring-shaped part 16b connecting to the n-pad part 16a. Similarly, the p-electrode 17 has a p-pad part 17a and a p-wiring-shaped part 17b connecting to the p-pad part 17a. The n-pad part 16a and the p-pad part 17a are parts connecting to bonding wires, and the n-wiring-shaped part 16b and the p-wiring-shaped part 17b are parts that diffuse electric current in the face to enhance uniformity of light emission. As shown in FIGS. 1 and 2, the n-electrode 16 and the p-electrode 17 are formed at the same plane side. The n-electrode 16 and the p-electrode 17 are covered with a protective film 20, except for the n-pad part 16a and the p-pad part 17a.

A plurality of via holes 18 are provided in the protective film 15. Through the via holes 18, the n-type layer 11 exposed on the bottom of the groove 19 is connected to the n-wiring-shaped part 16b, and the transparent electrode 14 on the p-type layer is connected to the wiring-shaped part 17b.

Regarding each constitution of the light-emitting element of Example 1, the specific constitution example and the like are described in detail below.

The substrate 10 is a c-plane sapphire substrate, and is a growth substrate that grows a group III nitride semiconductor on the surface thereof. Other than sapphire, the material of the substrate 10 can use SiC, Si, ZnO, spinel and the like.

The n-type layer 11, the light-emitting layer 12 and the p-type layer 13 can employ an optional structure conventionally known. For example, a structure that an n-contact layer, an ESD layer and an n-clad layer are laminated in the order from the substrate side can be used as the n-type layer 11. A superlattice structure in which n-GaN is repeatedly laminated can be used as the n-contact layer, a superlattice structure in which GaN/n-GaN is repeatedly laminated can be used as the ESD layer, and a superlattice structure in which InGaN/GaN/n-GaN is repeatedly laminated can be used as the n-clad layer. The indication “/” used here means lamination, and A/B means that a layer A is film-formed and a layer B is then film-formed thereon. Hereinafter, the same is applied to the explanation of materials. For example, an MQW structure in which AlGaN/InGaN/GaN is repeatedly laminated can be used as the light-emitting layer 12. For example, a structure in which the p-clad layer and the p-contact layer are laminated in the order from the light-emitting layer 12 side can be used as the p-type layer 13. A superlattice structure in which InGaN/p-AlGaN is releatedly laminated can be used as the p-clad layer, and p-GaN can be used as the p-contact layer. For the formation of the n-type layer, the light-emitting layer 12 and the p-type layer 13, an MOCVD method, an MBE method and the like can be used.

The transparent electrode 14 comprises ITO, and is formed on nearly the entire surface of the p-type layer 13 (the face opposite the light-emitting layer 12 side). The transparent electrode 14 can be formed by a method such as vacuum deposition or sputtering. The transparent electrode 14 comprises a material having translucency (permeability to light emission wavelength of the light-emitting element of Example 1). ICO (cerium-doped indium oxide), IZO (zinc-doped indium oxide), ZnO, TiO₂, NbTiO₂, TaTiO₂, graphene and the like can be used other than ITO.

The protective films 15 and 20 comprise SiO₂. The protective films 15 and 20 can be formed by sputtering, a CVD method or the like. Other than SiO₂, optional materials having translucency and insulating property can be used. The protective film may be constituted of a plurality of layers comprising different materials. For example, SiNₓ, Al₂O₃, HfO₂, ZrO₂, AlN, Al₂O₃/SiO₂, SiO₂/ZrO₂, SiO₂/Al₂O₃, SiO₂/HfO₂, SiN/SiO₂, Al₂O₃/ZrO₂, SiN/SiO₂/ZrO₂, SiO₂/Al₂O₃/HfO₂, and the like can be used. Materials of the protective film 15 and the protective film 20 may be different. A reflective film may be provided inside of the protective film 15 and at the position overlapping the n-electrode 16 and the p-electrode 17 in a planar view, and light emitted from the light-emitting layer 12 may be reflected by the reflective film, thereby absorption of light by the n-electrode 16 and the p-electrode 17 is suppressed, and the light extraction efficiency is enhanced.

The n-electrode 16 comprises V/Ni, Ti/AI, V/Au, Ti/Au, Ni/Au or the like, and the p-electrode 17 comprises Ni/Au, Pd/Au or the like. The n-electrode 16 may change the material and the thickness by the n-pad part 16a and the n-wiring-shaped part 16b. This makes it possible to optimize connectivity of the n-pad part 16a to a bonding wire, current diffuseness of the n-wiring-shaped part 16b, and adhesiveness to the protective film 15. The same can be applied to the n-electrode 17. The n-electrode 16 and the p-electrode 17 can be simultaneously formed by that the n-electrode 16 and the p-electrode 17 comprise the same material. The n-electrode 16 and the p-electrode 17 are formed by vacuum deposition, sputtering or the like. In forming the n-electrode 16, the n-pad part 16a and the n-wiring-shaped part 16b may be formed separately, and may be simultaneously formed. The same is applied to the p-electrode 17. However, from the standpoint of reduction in the number of steps, and the lie, simultaneous formation is preferred.

As shown in FIG. 1, the n-electrode 16 and the p-electrode 17 are arranged point-symmetrically. The n-wiring-shaped part 16b is formed in a straight line shape along one long side 1a of the element. The distance between the n-wiring-shaped part 16b and the long side 1a is b. The p-wiring-shaped part 17b is formed in a straight line shape along other long side 1b of the element. The distance between the p-wiring-shaped part 17b and the long side 1b is also b. The distance between the n-wiring-shaped part 16b and the p-wiring-shaped part 17b is a. The distances a and b satisfy 1.65≦a/b≦7.00. It should be noted that the indication “/” used here is not “/” in the explanation of materials, but means division. Width L of the n-wiring-shaped part 16b and the p-wiring-shaped part 17b is desirably from 1 to 50 μm. Where the length is narrower than 1 μm, electric current diffuseness is deteriorated, which is not desirable. Where the length is wider than 50 μm, light extraction efficiency is deteriorated by light interception by the n-wiring-shaped part 16b and p-wiring-shaped part 17b themselves, which is not desirable.

The patterns of the n-wiring-shaped part 16b and p-wiring-shaped part 17b are not limited to the pattern shown in FIG. 1, and may be optional pattern so long as it is a wiring shape extending in a long side direction. The “wiring shape” is not limited to the case of a straight line shape, but includes a curved line shape such as a curved shape, a zigzag shape or wavy line shape in a range that the whole or a part satisfies 1.65≦a/b≦7.00. In the case of a straight line shape, the line may have an angle of from −20 to 20° to a long side. All parts of the n-wiring-shaped part 16b and the p-wiring-shaped part 17b are not required to be a wiring shape extending in a long side direction, and a part, for example, the vicinity of the n-pad part 16a and the p-pad part 17a, may be a wiring shape intending in a direction different from a long side direction (for example, a short side direction). However, of the n-wiring-shaped part 16b and the p-wiring-shaped part 17b, the part extending in a direction different from a long side direction is desirably 50% or less of the whole. The reason for this is that electric current is made to diffuse efficiently. The n-wiring-shaped part 16b and the p-wiring-shaped part 17b are not required to be a single line shape, but may be a plurality of lines. In the case of a plurality of lines, the n-wiring-shaped part 16b and the p-wiring-shaped part 17b may be arranged alternately in a short side direction. For uniform light emission, the patterns of the n-wiring-shaped part 16b and the p-wiring-shaped part 17b are preferably a pattern having symmetry such as line symmetry or rotation symmetry.

In the patterns of the n-wiring-shaped part 16b and the p-wiring-shaped part 17b as described above, the distances a and b are defined as follows. The distance a is a distance between the n-wiring-shaped part 16b and the p-wiring-shaped part 17b in the wiring-shaped parts extending in a long side direction of the n-wiring-shaped part 16b and the p-wiring-shaped part 17b, and in the case that the wiring-shaped parts are curved or are not parallel to each other, the distance a is the shortest distance between the n-wiring-shaped part 16b and the p-wiring-shaped part 17b. The distance b is the shortest distance of from a long side of an outer periphery of the element to a wiring-shaped part extending in a long side direction of either of the n-wiring-shaped part or the p-wiring-shaped part, and in the case that the wiring-shaped part is curved or is not parallel to the long side, the distance b is the shortest distance. The distance b is desirably a distance of 0.1 times or more the length of the short side of the outer periphery of an element that is a rectangle. The reason for this is that local concentration of electric current is suppressed, and uniformity of light emission is further enhanced.

FIG. 6 is a view showing one example of a pattern of other n-electrode 26 and p-electrode 27. The n-electrode 26 and p-electrode 27 are arranged line-symmetrically. The n-electrode 26 comprises an n-pad part 26a and an n-wiring-shaped part 26b, and the p-electrode 27 comprises a p-pad part 27a and a p-wiring-shaped part 27b. The n-pad part 26a is located in the vicinity of one short side, and the p-pad part 27a is located in the vicinity of other short side. The n-wiring-shaped part 26b is one straight line-shaped pattern extending along long sides 1a and 1b at the center of an element. The p-wiring-shaped part 27b is two straight line-shaped patterns extending along the long sides 1a and 1b of the element. Of the two straight line-shaped patterns, one pattern is located between the long side 1a and the n-wiring-shaped part 26b, and other pattern is located between the long side 1b and the n-wiring-shaped part 26b. The distance between the long side 1a and the p-wiring-shaped part 27b, and the distance between the long side 1b and the p-wiring-shaped part 27b are b, the distance between the n-wiring-shaped part 26b and the p-wiring-shaped part 27b is b, and 1.65≦a/b≦7.00 is satisfied.

The via hole 18 is a hole opened in the protective film 15 and penetrating through the protective film 15 in a thickness direction (direction vertical to a main face of the substrate 10). The shape of the via hole is optional and can be, for example, a columnar shape or a prism shape. The via hole 18 is provided at a position connecting the n-type layer 11 exposed on the bottom of the groove 19 to the n-wiring-shaped part 16b, and at a position connecting the transparent electrode 14 to the p-wiring-shaped part 17b. Conduction between the n-type layer 11 and the n-wiring-shaped part 16b and between the transparent electrode 14 and the p-wiring-shaped part 17b may be achieved by directly embedding the n-electrode 16 and the p-electrode 17 in the via hole 18, or conduction may be achieved by embedding materials different from the n-wiring-shaped part 16b and the p-wiring-shaped part 17b in the via hole 18. Furthermore, a dot-shaped electrode may be provided on the n-type layer 11 at a position where the via hole 18 is formed and on the transparent electrode 14, thereby connecting the dot-shaped electrode to the n-wiring-shaped part 16b and the p-wiring-shaped part 17b through the via hole 18. By this constitution, ohmic property to a semiconductor layer can be independently controlled by the dot-shaped electrode, and electric current diffuseness can be independently controlled by the n-wiring-shaped part 16b and the p-wiring-shaped part 17b.

The n-pad part 16a, the p-pad part 17a, the n-wiring-shaped part 16b and the p-wiring-shaped part 17b may not be provided on the same plane. In other words, the constitution may be that a protective film is further provided on the n-wiring-shaped part 16 and the p-wiring-shaped part 17b, and the n-pad 16a and p-pad part 17a connecting through the via hole are provided on the protective film.

The n-type layer 11 and the n-wiring-shaped part 16b, and the transparent electrode 14 and the p-wiring-shaped part 17b may be connected through a single via hole 18, and may be connected through a plurality of via holes.

One n-pad part 16a and one p-pad part 17a are provided in the light-emitting element of Example 1, but a plurality of any one of the n-pad part 16a and the p-pad part 17a, or both may be provided. The position of the n-pad part 16a and the p-pad part 17a in a planar view is preferably that considering easiness of the attachment of bonding wire and electric current diffuseness, the n-pad part 16a is provided in the vicinity of the short side 2a of the element, and the p-pad part 17a is provided in the vicinity of other short side 2b. In Example 1, the shape of the n-pad part 16a and the p-pad part 17a is a circular shape. However, the shape can be any optional shape, and the n-pad part 16a and the p-pad part 17a can have different shape.

The light-emitting element of Example 1 has the constitution that the n-electrode 16 and the p-electrode 17 are provided on the protective film 15, and conduction is achieved through the via hole 18 opened in the protective film 15, as described above. However, the light-emitting element may have the constitution that the protective film 15 is not provided, and the n-electrode 16 and the p-electrode 17 are directly provided on the n-type layer 11 and on the transparent electrode 14.

In the light-emitting element of Example 1 described above, when the distance a is a distance between the n-wiring-shaped part 16b and the p-wiring-shaped part 17b, and the distance b is a distance between the long side 1a of the element that is a rectangle in a planar view and the n-wiring-shaped part 16a and a distance between the long side 1b and the p-wiring-shaped part 17b, the n-wiring-shaped part 16b and the p-wiring-shaped part 17b are arranged so as to satisfy 1.65≦a/b≦7.00. Therefore, electric current diffuses uniformly, local concentration is inhibited, and as a result, deterioration of light emission efficiency can be suppressed.

The light-emitting element of Example 1 is preferable to the case of a rectangular shape in which a ratio of a long side to a short side is 2 or more. A long light-emitting element having such a large aspect ratio cannot uniformly diffuse electric current conventionally, local concentration of electric current occurs, and light emission efficiency has been deteriorated. However, according to the light-emitting element of Example 1, even though the element has such a long shape, the element can uniformly diffuse electric current and can suppress deterioration of light emission efficiency. Furthermore, such a long light-emitting element is useful as a light-emitting element mounted on a side view-type LED package used as a backlight source of a liquid crystal display and the like.

### Test Example

A plurality of light-emitting elements having different distance a and distance b (the constitution other than the distances a and b are the same constitution as the light-emitting element of Example 1) was prepared, light output and pressure resistance were measured, and a/b dependency of the light output and the pressure resistance of the elements were examined. The light-emitting element is a rectangular light-emitting element of 600 μm×240 μm in a planar view.

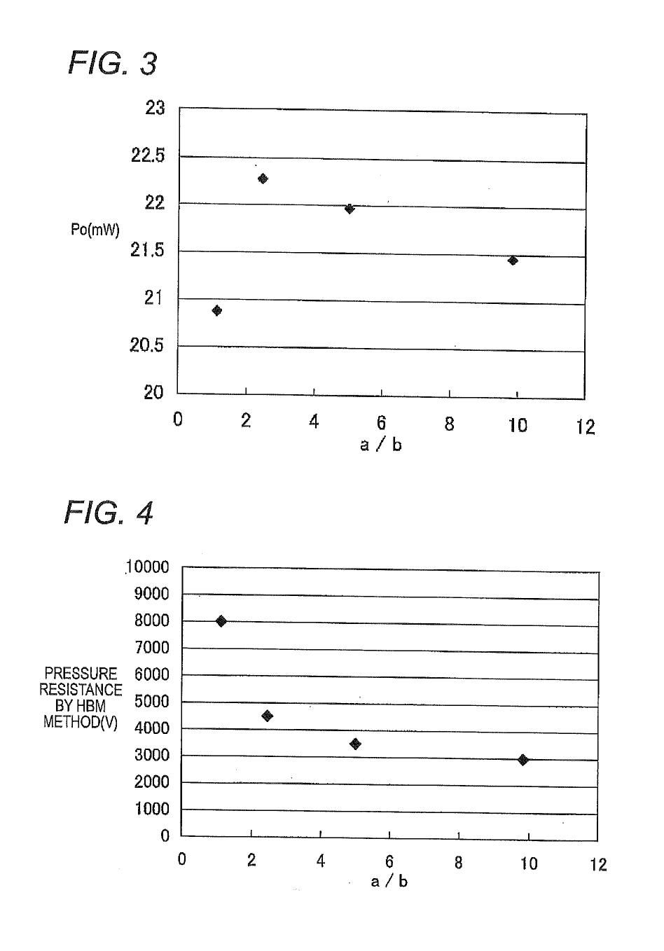

FIG. 3 is a graph showing the relationship between light output and a/b in a light emitting element. As shown in FIG. 3, it is seen that the light output greatly changes at a/b=1.65, and the light output is greatly increased at a/b≧1.65. This is considered that by that the n-wiring-shaped part 16b and the p-wiring-shaped part 17b are arranged so as to satisfy a/b≧1.65, electric current diffuses uniformly, local concentration of electric current is relaxed, and light emission efficiency is improved. Furthermore, it is seen that when a/b exceeds 1.65, the light output is greatly increased up to the vicinity of a/b=2.5, but when the output exceeds a/b=2.5, the light output is gradually decreased. In order that the light output is higher than the light output of the conventional element, a/b≦7.00 must be satisfied. Specifically, the a/b is desirably 1.65≦a/b≦7.00.

FIG. 4 is a graph showing the relationship between pressure resistance and a/b in the light-emitting element. The pressure resistance is a value measured by an HBM method (human body model). As shown in FIG. 4, the pressure resistance of the light-emitting element is decreased with increasing a/b. Particularly, up to a/b=3.85, the pressure resistance is greatly decreased with increasing a/b. However, when the a/b exceeds 3.85, the decrease in the pressure resistance is very mild. Thus, the reason that the pressure resistance is enhanced when a/b is decreased is considered that by that the distance of electric current flowing in group III nitride semiconductor crystals becomes short, electric current flowing to crystal defects is decreased. The pressure resistance at a/b=3.85 is about 4,000V. Because the pressure resistance of the conventional light-emitting element is 4,000V, a/b≦3.85 is desirable such that the pressure resistance of the light-emitting element of Example is larger than 4,000V. In view of the above, from the graphs of FIGS. 3 and 4, the most desirable range is 1.65≦a/≦3.85.

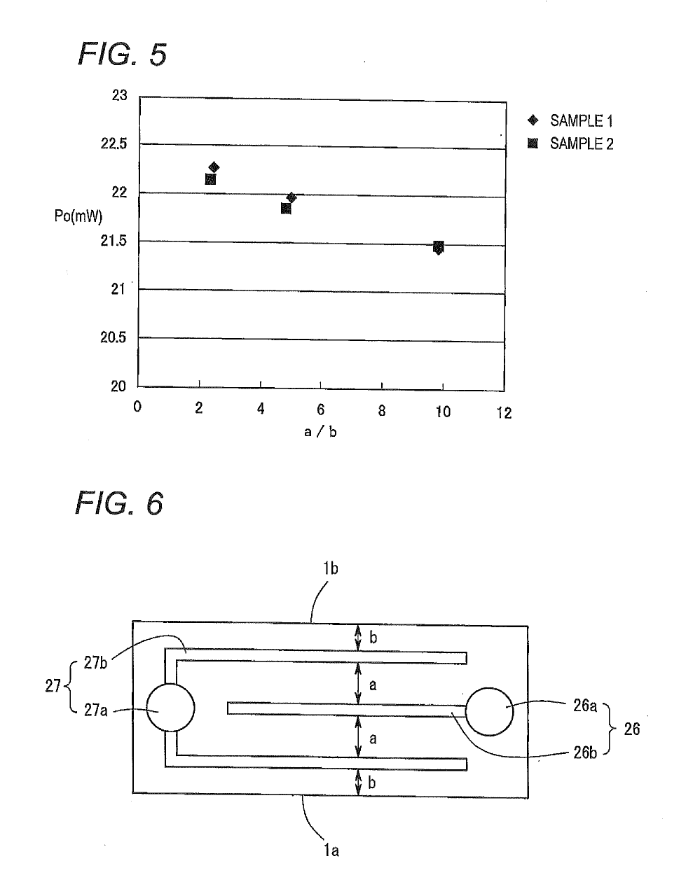

FIG. 5 is a graph showing how the relationship between the light output and a/b changes in the case of changing the number of via holes 18 of the light-emitting element of Example 1. Sample 1 is that the number of the vial hole 18 connecting the n-wiring-shaped part 16b to the n-type layer 11 is one, and the number of the via hole 18 connecting the p-wiring-shaped part 17b to the transparent electrode 14 is two. Sample 2 is that the number of the vial hole 18 connecting the n-wiring-shaped part 16b to the n-type layer 11 is two, and the number of the via hole 18 connecting the p-wiring-shaped part 17b to the transparent electrode 14 is three.

As shown in FIG. 5, it is seen that when the value of a/b is small, the light output of Sample 1 tends to be slightly larger than that of Sample 2, but the tendency that the light output is gradually decreased with increasing a/b in the range that a/b is 2.5 or larger is the same in any case of Samples 1 and 2. From the results of FIG. 3 and FIG. 5, it can be imagined that even though the number of via hole 18 differs, if the n-wiring-shaped part 16b and the p-wiring-shaped part 17b are arranged so as to satisfy 1.655≦a/b≦7.00, local concentration of electric current is relaxed and deterioration of emission efficiency can be suppressed. From the fact that great difference in tendency is not observed in the relationship between light output and a/b even though the number of the via hole 18 differs, it can be further imagined that even in the case that the p-electrode 17 has been simply formed directly on the p-type layer 13 or the transparent electrode 14 without through the protective film 15, and even in the case that the n-electrode 16 is directly formed on the n-type layer 11, if 1.65≦a/b≦7.00 is satisfied, local concentration of electric current is relaxed, and deterioration of emission efficiency can be suppressed.

It was seen from the above Test Example that when the n-wiring-shaped part 16b and the p-wiring-shaped part 17b are arranged so as to satisfy 1.65≦a/b≦7.00, electric current can be efficiency diffused, local concentration of electric current can be relaxed, and as a result, deterioration of light emission efficiency can be suppressed. It was further seen from the above Test Example that further desirable result is obtained when 1.65≦a/b≦3.85 is satisfied.

The group III nitride semiconductor light-emitting element of the present invention can be used in a lighting device, a display device and the like. In particular, the group III nitride semiconductor light-emitting element of the present invention is suitable as a light-emitting element mounted on a side-view type LED package used as a backlight source of liquid crystal.

What is claimed is:

1. A group III nitride semiconductor light-emitting element having a rectangular shape in a planar view, the element comprising:
an n-electrode connecting to an n-type layer and a p-electrode connecting to a p-type layer, on a same plane side;
wherein the n-electrode has a n-wiring-shaped part that is wiring-shaped and extending along a first side of the rectangular shape;
the p-electrode has a p-wiring-shaped part that is wiring-shaped and extending along the first side of the rectangular shape; and
when a distance that is between the n-wiring-shaped part and the p-wiring-shaped part is a, and a distance that is between the one side of the rectangular shape and at least one of the n-wiring-shaped part and the p-wiring-shaped part and that is nearest to the first side is b, the n-wiring-shaped part and the p-wiring-shaped part are arranged such that the distances a and b satisfy 1.65≦a/b≦7.00.

2. The group III nitride semiconductor light-emitting element according to claim 1, wherein the n-wiring-shaped part and the p-wiring-shaped part are arranged such that the distances a and b satisfy a/b≦3.85.

3. The group III nitride semiconductor light-emitting element according to claim 1, wherein a protective film comprising an insulator is present between the n-type layer and the n-electrode, and between the p-type layer and the p-electrode; and
the n-wiring-shaped part of the n-electrode is connected to the n-type layer through a via hole provided in the protective film, and the p-wiring-shaped part of the p-electrode is connected to the p-type layer through the via hole.

4. The group III nitride semiconductor light-emitting element according to claim 1, wherein the n-wiring-shaped part and the p-wiring-shaped part have a straight line shape in parallel to the one side of the rectangle.

5. The group III nitride semiconductor light-emitting element according to claim 1, wherein the first side is a long side of the rectangular shape.

6. The group III nitride semiconductor light-emitting element according to claim 5, wherein the element is a rectangle having a ratio of the long side to a short side of 2 or more.
